(19) United States
(12) Patent Application Publication
(10) Pub. No.: US 2026/0107795 A1
(43) Pub. Date: Apr. 16, 2026

(54) SEMICONDUCTOR PACKAGE

(71) Applicant: Samsung Electronics Co., Ltd., Suwon-si (KR)

(72) Inventor: Junghoon Kang, Suwon-si (KR)

(21) Appl. No.: 19/251,617

(22) Filed: Jun. 26, 2025

(30) Foreign Application Priority Data
Oct. 14, 2024 (KR) 10-2024-0139731

(51) Int. Cl. H01L 23/538; H01L 23/00; H01L 23/31; H01L 23/34; H01L 23/48; H01L 23/498; H01L 25/04

(52) U.S. Cl. CPC H10W 70/614; H10W 20/20; H10W 40/00; H10W 70/611; H10W 70/635; H10W 70/65; H10W 74/111; H10W 90/00; H10W 90/26; H10W 90/794

(57) ABSTRACT

Provided is a semiconductor package including an interposer, a first semiconductor chip stack arranged on the interposer and including a plurality of first semiconductor chips, a second semiconductor chip stack arranged on the interposer and including a plurality of second semiconductor chips, and spaced apart from the first semiconductor chip stack in a lateral direction, and a first bridge chip arranged on the interposer, wherein the interposer includes a second wiring structure, a first wiring structure spaced apart from the second wiring structure upwardly, a first embedded semiconductor chip and a second embedded semiconductor chip arranged between the first wiring structure and the second wiring structure, and a plurality of first conductive posts arranged between the first embedded semiconductor chip and the second embedded semiconductor chip.

### CROSS-REFERENCE TO RELATED APPLICATION

This application is based on and claims ranking under 35 U.S.C. § 119 to Korean Patent Application No. 10-2024-0139731, filed on Oct. 14, 2024, in the Korean Intellectual Property office, the disclosure of which is incorporated by reference herein in its entirety.

### BACKGROUND

The inventive concept relates to a semiconductor package, and more particularly, to a semiconductor package including a semiconductor chip stack.

Recently, a demand on portable devices has rapidly increased in the electronic products market, and accordingly, miniaturization and reducing weight of the electronic components mounted on the electronic products are continuously performed. For the miniaturization and reducing weight of the electronic components, the semiconductor packages mounted thereon are required to process a large amount of data while the volume thereof is reduced. Accordingly, semiconductor packages including a plurality of semiconductor chips are being developed. For example, a semiconductor package including an embedded semiconductor chip inside an interposer, or including a plurality of semiconductor chips on the interposer may be used.

### SUMMARY

Aspects of the inventive concept provide a semiconductor package in which thermal characteristics are improved, and signal transfer between semiconductor chips is improved.

Issues to be solved by the inventive concept are not limited to the above-mentioned issues, and other issues not mentioned may be clearly understood by those of ordinary skill in the art from the following descriptions.

According to an aspect of the inventive concept, there is provided a semiconductor package including an interposer, a first semiconductor chip stack arranged on the interposer and including a plurality of first semiconductor chips, a second semiconductor chip stack arranged on the interposer and including a plurality of second semiconductor chips, the second semiconductor chip stack spaced apart from the first semiconductor chip stack in a lateral direction, and a first bridge chip arranged on the interposer between the first semiconductor chip stack and the second semiconductor chip stack, wherein the interposer includes a second wiring structure, a first wiring structure spaced apart from the second wiring structure in a vertical direction, a first embedded semiconductor chip arranged between the first wiring structure and the second wiring structure, a second embedded semiconductor chip arranged between the first wiring structure and the second wiring structure, and spaced apart from the first embedded semiconductor chip in a lateral direction, and a plurality of first conductive posts arranged between the first embedded semiconductor chip and the second embedded semiconductor chip.

According to another aspect of the inventive concept, there is provided a semiconductor package including an interposer, a plurality of semiconductor chip stacks arranged on the interposer and respectively including a plurality of semiconductor chips and a bridge chip arranged on the interposer, wherein the interposer includes a second wiring structure, a first wiring structure spaced apart from the second wiring structure in a vertical direction, a first embedded semiconductor chip arranged between the first wiring structure and the second wiring structure, a second embedded semiconductor chip arranged between the first wiring structure and the second wiring structure, the second embedded semiconductor chip spaced apart from the first embedded semiconductor chip in a lateral direction, and a plurality of first conductive posts arranged between the first embedded semiconductor chip and the second embedded semiconductor chip, wherein the first embedded semiconductor chip overlaps a first group of semiconductor chips of the plurality of semiconductor chips in the vertical direction, and the second embedded semiconductor chip overlaps a second group of semiconductor chips of the plurality of semiconductor chips in the vertical direction, and wherein a first portion of the bridge chip overlaps the first embedded semiconductor chip in the vertical direction, and a second portion of the bridge chip overlaps the second embedded semiconductor chip in the vertical direction.

According to another aspect of the inventive concept, there is provided a semiconductor package including an interposer, a first semiconductor chip stack arranged on the interposer and including a plurality of first semiconductor chips, a second semiconductor chip stack arranged on the interposer and including a plurality of second semiconductor chips and spaced apart from the first semiconductor chip stack in a lateral direction, a bridge chip arranged on the interposer between the first semiconductor chip stack and the second semiconductor chip stack, a first heat dissipation block arranged on the first bridge chip between the first semiconductor chip stack and the second semiconductor chip stack, a second heat dissipation block on the interposer and configured to extend along an outer edge of the interposer and to extend between the first semiconductor chip stack and the second semiconductor chip stack, and spaced apart from the first heat dissipation block, wherein the interposer includes a second wiring structure, a first wiring structure apart from the second wiring structure upwardly, a first embedded semiconductor chip arranged between the first wiring structure and the second wiring structure, a second embedded semiconductor chip arranged between the first wiring structure and the second wiring structure, the second embedded semiconductor chip apart from the first embedded semiconductor chip in a lateral direction, and a plurality of first conductive posts arranged between the first embedded semiconductor chip and the second embedded semiconductor chip, and a plurality of second conductive posts, wherein the plurality of second conductive posts are arranged between the first wiring structure and the second wiring structure, and a first group of second conductive posts of the plurality of second conductive posts are arranged between an outer edge of the interposer and the first embedded semiconductor chip, and a second group of second conductive posts of the plurality of second conductive posts are arranged between the outer edge of the interposer and the second embedded semiconductor chip, wherein the first wiring structure includes a first insulating layer and a plurality of first via patterns, wherein the first embedded semiconductor chip includes a plurality of first electrodes configured to extend in a vertical direction inside the first embedded semiconductor chip, and the second embedded semiconductor chip includes a plurality of second electrodes configured to extend in a vertical direction inside the second embedded semiconductor chip, wherein the first wiring structure is in contact with a first surface of the first embedded semiconductor chip and a second surface of the second embedded semiconductor chip, and the second wiring structure is in contact with a third surface of the first embedded semiconductor chip opposite the first surface and a fourth surface of the second embedded semiconductor chip opposite the second surface, wherein a first conductive post of the plurality of first conductive posts supplies power to the first bridge chip, and a second conductive post of the plurality of second conductive posts supplies power to the first semiconductor chip stack, and wherein each of a first active surface of the first embedded semiconductor chip and a second active surface of the second embedded semiconductor chip is arranged closer to the first wiring structure than the second wiring structure.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is a plan view of a semiconductor package according to an embodiment;

FIG. 3 is a cross-sectional view of a semiconductor package according to an embodiment;

FIG. 4 is a plan view of a semiconductor package according to an embodiment;

FIG. 5 is a cross-sectional view of a semiconductor package according to an embodiment;

FIG. 6 is a plan view of a semiconductor package according to an embodiment;

FIG. 7 is a cross-sectional view of a semiconductor package according to an embodiment;

FIG. 8 is a plan view of a semiconductor package according to an embodiment;

FIG. 9 is a cross-sectional view of a semiconductor package according to an embodiment;

FIG. 10 is a plan view of a semiconductor package according to an embodiment; and

FIGS. 11A, 11B, 11C, 11D, 11E, and 11F are cross-sectional views sequentially illustrating a manufacturing method of a semiconductor package according to embodiments.

### DETAILED DESCRIPTION OF THE EMBODIMENTS

Hereinafter, example embodiments of the inventive concept are described in detail with reference to the accompanying drawings.

Embodiments of the inventive concept are provided to more completely explain the technical idea of the inventive to those of skill in the art, and the embodiments below may be modified in various different forms, and the scope of the inventive concept is not limited thereto. Rather, the embodiments are provided to convey the idea of the inventive concept to those of skill in the art. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention. In addition, the thickness or size of each layer in the drawings is exaggerated for convenience and clarity of explanation.

In the following disclosure, a first direction may mean the X direction, a second direction may mean the Y direction, and the first direction may be perpendicular to the second direction. A third direction may mean the Z direction, and the third direction may be perpendicular to both the first direction and the second direction. The third direction may be a vertical direction, relative to a base horizontal surface such a lower surface of a substrate. A horizontal plane or a flat surface may be referred to as an X-Y plane. The upper surface of a specific object means one surface located in a positive third direction with respect to the specific object, and the lower surface of the specific object means one surface located in a negative third direction with respect to the specific object.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

As used herein, the term “integral body” may refer to structures, patterns, and/or layers that are formed at the same time and of the same material, without a break in the continuity of the material of which they are formed. As one example, structures, patterns, and/or layers that are integral bodies may be homogeneous monolithic structures.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

It will be appreciated that “planarization,” “co-planar,” “planar,” etc., as used herein refer to structures (e.g., surfaces) that need not be perfectly geometrically planar, but may include acceptable variances that may result from standard manufacturing processes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Items described in the singular herein may be provided in plural, as can be seen, for example, in the drawings. Thus, the description of a single item that is provided in plural should be understood to be applicable to the remaining plurality of items unless context indicates otherwise.

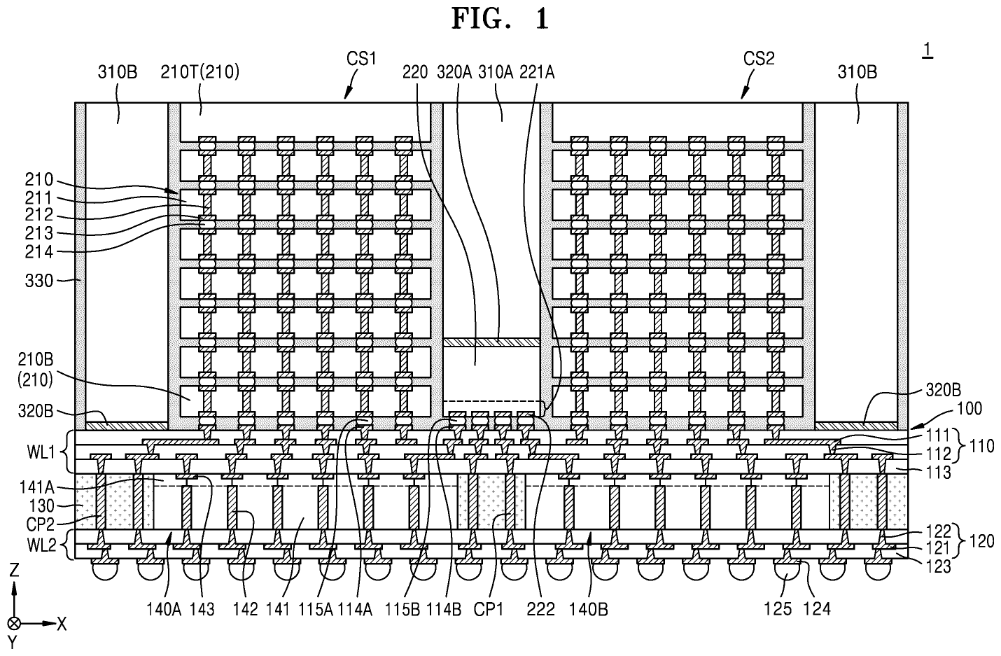

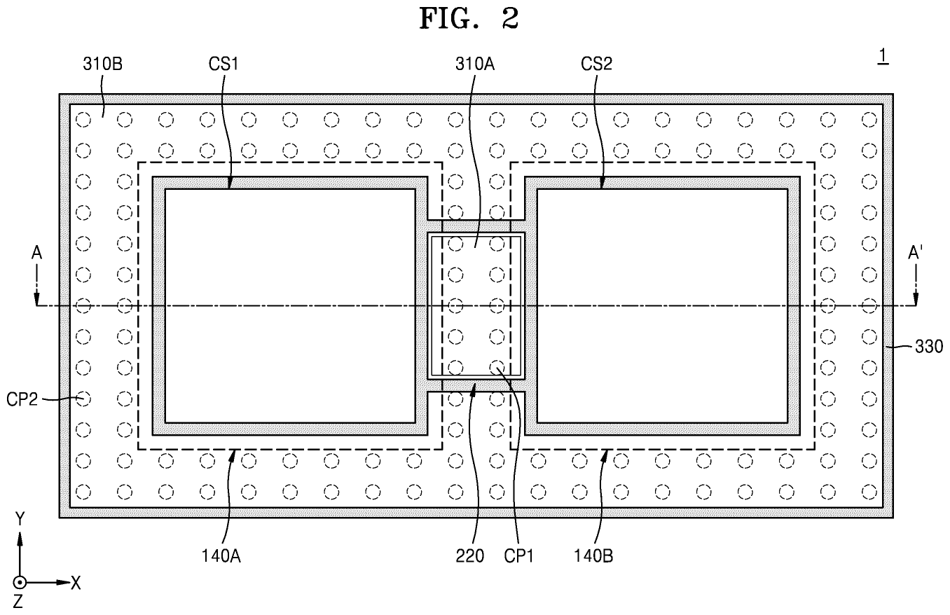

FIG. 1 is a cross-sectional view of a semiconductor package 1 according to an embodiment. FIG. 2 is a plan view of the semiconductor package 1 according to an embodiment. FIG. 1 is a cross-sectional view taken along cutting line A-A′ in FIG. 2.

Referring to FIGS. 1 and 2, the semiconductor package 1 may include an interposer 100, a first semiconductor chip stack CS1 provided on the interposer 100, a second semiconductor chip stack CS2 spaced apart from the first semiconductor chip stack CS1 in a lateral direction on the interposer 100, a first bridge chip 220 provided between the first semiconductor chip stack CS1 and the second semiconductor chip stack CS2, a first heat dissipation block 310A provided on the first bridge chip 220 between the first semiconductor chip stack CS1 and the second semiconductor chip stack CS2, and a second heat dissipation block 310B provided on the interposer 100 to extend along an outer edge of the interposer 100.

The interposer 100 may include a second wiring structure WL2, a first embedded semiconductor chip 140A provided on the second wiring structure WL2, a second embedded semiconductor chip 140B spaced apart from the first embedded semiconductor chip 140A in a lateral direction on the second wiring structure WL2, a plurality of first conductive posts CP1 provided between the first embedded semiconductor chip 140A and the second embedded semiconductor chip 140B, a plurality of second conductive posts CP2 provided on the second wiring structure WL2 between the outer edge of the second wiring structure WL2 and the first embedded semiconductor chip 140A and between the outer edge of the second wiring structure WL2 and the second embedded semiconductor chip 140B, a first encapsulating member 130 and a first wiring structure WL1. The second wiring structure WL2 may be a first wiring layer and the first wiring structure WL1 may be a first wiring layer. The first encapsulating member 130 surrounds the plurality of first conductive posts CP1, the plurality of second conductive posts CP2, the first embedded semiconductor chip 140A, and the second embedded semiconductor chip 140B. The first wiring structure WL1 is provided on the first embedded semiconductor chip 140A, the second embedded semiconductor chip 140B, and the first encapsulating member 130. Each of the first and/or second embedded semiconductor chip 140A, 140B may be a logic chip. Each of the first and/or second embedded semiconductor chip 140A, 140B may perform logic function for memory chips such as bus interface functions for communicating with the memory chips.

The second wiring structure WL2 may include one or more second insulating layers 123 and a plurality of second wiring patterns 120 which may be rewiring patterns. The second wiring pattern 120 may include a plurality of second line patterns 121 and a plurality of second via patterns 122.

The second insulating layer 123 may surround the plurality of second wiring patterns 120. In some embodiments, the second wiring structure WL2 may include a plurality of second insulating layers 123 which are stacked. The second insulating layer 123 may be formed of and/or include, for example, photo imageable dielectric (PID) or photosensitive polyimide (PSPI).

A passivation layer may be provided under a lower surface of the second wiring structure WL2. The passivation layer may protect the second wiring structure WL2 and may include a polymer. The passivation layer may cover at least a portion of side surfaces and a lower surface of each of a plurality of external connection pads 124.

A plurality of second wiring patterns 120 may include the plurality of second line patterns 121 and the plurality of second via patterns 122. The plurality of second wiring patterns 120 may be formed of and/or include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof, but are not limited thereto.

The plurality of second line patterns 121 may be arranged on at least one of an upper surface and a lower surface of the second insulating layer 123. For example, when the second wiring structure WL2 includes the plurality of second insulating layers 123, the plurality of second line patterns 121 may be arranged between an upper surface of the second insulating layer 123 that is uppermost, a lower surface of the second insulating layer 123 that is lowermost, and neighboring second insulating layers 123.

The plurality of second via patterns 122 may penetrate the second insulating layer 123 and be connected to some of the plurality of second line patterns 121. In some embodiments, each of the second via patterns 122 may have a tapered shape in which a horizontal width decreases towards the first encapsulating member 130, and which extends vertically. For example, each of the second via patterns 122 may have a tapered shape in which the horizontal width increases away from the first encapsulating member 130.

In some embodiments, some of the plurality of second line patterns 121 may be formed together with at least some of the second via patterns 122 (e.g., a group of the second line patterns) to be integrated into one integral body. For example, the second line pattern 121 and the second via pattern 122 in contact with a lower surface of the second line pattern 121 may be formed together as one integral body.

Among the plurality of second wiring patterns 120, a group of second line wiring patterns 120 of the plurality of second wiring patterns 120 arranged adjacent to the lower surface of the second wiring structure WL2 may be referred to as a plurality of external connection pads 124. Alternatively, the plurality of external connection pads 124 may be a group of second line patterns 121 of the plurality of second line patterns 121 arranged adjacent to the lower surface of the second wiring structure WL2.

External connection terminals 125 may be attached to the external connection pads 124, respectively. The plurality of external connection terminals 125 may connect the semiconductor package 1 to the outside. In some embodiments, the plurality of external connection terminals 125 may include solder bumps or solder balls.

The first embedded semiconductor chip 140A and the second embedded semiconductor chip 140B may be arranged apart from each other on the second wiring structure WL2. The first embedded semiconductor chip 140A and the second embedded semiconductor chip 140B may include logic semiconductor chips. The logic semiconductor chip may include, for example, a central processing unit (CPU), a graphics processing unit (GPU), a field programmable gate array (FPGA), an application processor (AP), a digital signal processor, an encryption processor, a controller, or an application specific integrated circuit (ASIC).

For example, the first embedded semiconductor chip 140A and the second embedded semiconductor chip 140B may include logic chips (e.g., control semiconductor chips) controlling the first semiconductor chip stack CS1 and the second semiconductor chip stack CS2 (for example, determining a data processing sequence, controlling prevention of errors and defective sectors, buffering to control loading, and using a frequency boosting interface (FBI)), or semiconductor chips with ASICs integrated therein.

The first embedded semiconductor chip 140A may include a first embedded substrate 141, a plurality of embedded through electrodes 142 (e.g., a through via) vertically penetrating at least a portion of the first embedded substrate 141, a first active surface 141A provided adjacent to an upper surface of the first embedded substrate 141, and a plurality of embedded chip pads 143.

The first embedded substrate 141 may be formed of and/or include, for example, a semiconductor material such as silicon (Si). Alternatively, the first embedded substrate 141 may be formed of and/or include a semiconductor material such as germanium (Ge). The first embedded substrate 141 may include the first active surface 141A and an inactive surface opposite to the first active surface 141A. The first embedded substrate 141 may include a conductive area, for example, a well doped with impurities. The first embedded substrate 141 may have various device isolation structures such as a shallow trench isolation (STI) structure.

A first semiconductor device formed on the first active surface 141A of the first embedded substrate 141 may include various types of individual devices. The plurality of individual devices may include various microelectronic devices, for example, a metal-oxide-semiconductor field effect transistor (MOSFET) such as a complementary metal-oxide-semiconductor (CMOS) transistor, an image sensor, such as a system large scale integration (LSI) sensor and a CMOS imaging sensor (CIS), a micro-electro-mechanical system (MEMS), an active device, a passive device, etc. The plurality of individual devices may be electrically connected to the conductive area of the first embedded substrate 141. The first semiconductor device may further include a conductive wiring or a conductive plug electrically connecting at least two individual devices to each other, or the plurality of individual devices to the conductive area of the first embedded substrate 141. In addition, each of the individual devices may be electrically isolated from another adjacent individual device by an insulating layer.

The first embedded substrate 141 may include a first wiring structure layer adjacent to the first active surface 141A. The first wiring structure layer may electrically connect the first semiconductor device provided on the first active surface 141A to a plurality of first through electrodes 142 and the plurality of embedded chip pads 143. In FIG. 1, the first wiring structure layer is schematically illustrated by a solid line connecting the plurality of first through electrodes 142 to the plurality of embedded chip pads 143. The first active surface 141A may be provided closer to an upper surface of the first embedded semiconductor chip 140A than a lower surface of the first embedded semiconductor chip 140A. For example, the first embedded semiconductor chip 140A may be arranged such that the first active surface 141A of the first embedded semiconductor chip 140A is closer to the first wiring structure WL1 than the second wiring structure WL2. This arrangement may be the same for the second embedded semiconductor chip 140B. For example, the second embedded semiconductor chip 140B may be arranged such that a second active surface of the second embedded semiconductor chip 140B is closer to the first wiring structure WL1 than the second wiring structure WL2.

The plurality of first conductive posts CP1 may be provided between the first embedded semiconductor chip 140A and the second embedded semiconductor chip 140B. The second conductive post CP2 may be provided on the second wiring structure WL2 along an outer edge of the second wiring structure WL2 or an outer edge of the interposer 100. For example, the plurality of second conductive posts CP2 may be provided between the outer edge of the first embedded semiconductor chip 140A and the second wiring structure WL2, and between the outer edge of the second embedded semiconductor chip 140B and the second wiring structure WL2. The first conductive posts CP1 and the second conductive posts CP2 may each be formed of a metal or other conductive material. The first conductive posts CP1 and the second conductive posts CP2 may each have a pillar shape, column shape, etc.

As illustrated in FIGS. 1 and 2, the plurality of second conductive posts CP2 may be arranged with the second conductive posts CP2 in two lines between the outer edge of the second wiring structure WL2 and the first embedded semiconductor chip 140A, and between the outer edge of the second wiring structure WL2 and the second embedded semiconductor chip 140B, and the plurality of first conductive posts CP1 may be arranged with the first conductive posts CP1 in two lines between the first embedded semiconductor chip 140A and the second embedded semiconductor chip 140B, but the inventive concept is not limited to this arrangement of the plurality of first conductive posts CP1 and the plurality of second conductive posts CP2.

At least some of the second conductive posts CP2 may supply power to the first semiconductor chip stack CS1 and the second semiconductor chip stack CS2. For example, a group of second conductive posts CP2 may supply power to the first semiconductor stack CP1 and/or the second semiconductor stack CP2. At least some of the second conductive posts CP2 may supply electrical signals to the first semiconductor chip stack CS1 and the second semiconductor chip stack CS2. For example, a group of second conductive posts CP2 may supply electrical signals to the first semiconductor stack CP1 and/or the second semiconductor stack CP2. Alternatively, at least some of the first conductive posts CP1 may supply power to the first semiconductor chip stack CS1 and the second semiconductor chip stack CS2, or at least some of the first conductive posts CP1 may transfer electrical signals to the first semiconductor chip stack CS1 and the second semiconductor chip stack CS2.

The first encapsulating member 130 may surround the plurality of first conductive posts CP1, the plurality of second conductive posts CP2, the first embedded semiconductor chip 140A, and the second embedded semiconductor chip 140B, on the second wiring structure WL2. The first encapsulating member 130 may include an epoxy mold compound (EMC), and may further include a filler.

A vertical thickness of the first encapsulating member 130 may be the same or substantially the same as a vertical thicknesses of the first embedded semiconductor chip 140A and the second embedded semiconductor chip 140B. A vertical distance between the upper surface of the second wiring structure WL2 and an upper end of the plurality of first conductive posts CP1 and a vertical distance between the upper surface of the second wiring structure WL2 an upper end of the plurality of second conductive posts CP2 may be substantially the same as the vertical thicknesses of the first embedded semiconductor chip 140A and the second embedded semiconductor chip 140B. For example, the upper ends of the plurality of first conductive posts CP1, the upper ends of the plurality of second conductive posts CP2, the upper surface of the first embedded semiconductor chip 140A, the upper surface of the second embedded semiconductor chip 140B, and upper surface of the first encapsulating member 130 may be coplanar.

The first wiring structure WL1 may be provided on the upper surface of the first encapsulating member 130. The first wiring structure WL1 may include a plurality of first insulating layers 113 and a plurality of first wiring patterns 110 which may be rewiring patterns. The first wiring patterns 110 may each include a plurality of first line patterns 111 and a plurality of first via patterns 112. Side surfaces of each of the first wiring structure WL1, the first encapsulating member 130, and the second wiring structure WL2 may be vertically aligned with one another.

The first insulating layer 113 may surround the plurality of first wiring patterns 110. In some embodiments, the first wiring structure WL1 may include a plurality of first insulating layers 113 which are stacked. Each of the first insulating layers 113 may be formed of and/or include, for example, PID or PSPI.

The plurality of first wiring patterns 110 may include the plurality of first line patterns 111 and the plurality of first via patterns 112. The plurality of first wiring patterns 110 may be formed of and/or include a metal, such as Cu, Al, W, Ti, Ta, In, Mo, Mn, Co, Sn, Ni, Mg, Re, Be, Ga, and Ru, or an alloy thereof, but are not limited thereto.

Each of the first line patterns 111 may be arranged on one of an upper surface and a lower surface of the first insulating layer 113. The plurality of first via patterns 112 may penetrate the first insulating layer 113 and be connected to some of the first line patterns 111. In some embodiments, each of the first via patterns 112 may have a tapered shape in which a horizontal width decreases towards the first encapsulating member 130, and extend vertically. For example, each of the first via patterns 112 may have a tapered shape in which a horizontal width increases towards a second encapsulation member 330 to be described below, and extend vertically.

In some embodiments, some of the first line patterns 111 may be formed together with a respective first via pattern 112 to be one integral body. For example, one of the first line patterns 111 and one of the first via patterns 122 in contact with a lower surface of the respective first line pattern 111 may be formed as one integral body.

A first group of the first wiring patterns 110 arranged adjacent to the upper surface of the first wiring structure WL1 may be referred to as a plurality of first upper connection pads 114A and a second group of the first wiring patterns 110 arranged adjacent to the upper surface of the first wiring structure WL1 may be referred to as a plurality of second upper connection pads 114B. Alternatively, the first upper connection pads 114A and the second upper connection pads 114B may include portions of first line patterns 111 that are arranged adjacent to the upper surface of the first wiring structure WL1.

Some of the first upper connection pads 114A may be electrically connected to a plurality of first chip pads 213 provided on a lower surface of a first semiconductor chip 210B that is lowermost in the first semiconductor chip stack CS1 as described below (e.g., a lowermost first semiconductor chip 210B), through some of first chip connection terminals 115A of a plurality of first chip connection terminals 115A. Similarly, some of the first upper connection pads 114A may be electrically connected to a plurality of first chip pads 213 provided on the lower surface of the first semiconductor chip 210B that is lowermost in the second semiconductor chip stack CS2 as described below, through some of the first chip connection terminals 115A. The plurality of second upper connection pads 114B may be electrically connected to a plurality of second chip pads 222 provided in the first bridge chip 220 to be described below, via a plurality of second chip connection terminals 115B.

The first semiconductor chip stack CS1 and the second semiconductor chip stack CS2 may be provided on the interposer 100. The first semiconductor chip stack CS1 may be spaced apart from the second semiconductor chip stack CS2, and the first bridge chip 220 may be provided on the interposer 100 between the first semiconductor chip stack CS1 and the second semiconductor chip stack CS2. The configuration of the second semiconductor chip stack CS2 may be the same as or substantially similar to that of the first semiconductor chip stack CS1.

The first semiconductor chip stack CS1 may include a plurality of first semiconductor chips 210. For example, as illustrated in FIG. 1, the first semiconductor chip stack CS1 may include eight first semiconductor chips 210, but the inventive concept is not limited thereto. Each of the first semiconductor chips 210 may include a first substrate 211, a plurality of first through electrodes 212 penetrating at least a portion of the first substrate 211, first chip pads 213 provided on an upper surface and/or a lower surface of the first substrate 211, and first chip connection terminals 214 respectively provided between the first chip pads 213 provided on each of the upper and lower surfaces of different first semiconductor chips 210 vertically adjacent to each other.

The first substrate 211 may include an active surface and an inactive surface that are opposite to each other, a first semiconductor device provided on the active surface of the first substrate 211, and a first wiring structure provided adjacent to the active surface of the first substrate. The active surface provided in each of the plurality of first semiconductor chips 210 may be provided closer to the lower surface of a respective first semiconductor chip 210 than to the upper surface of the respective first semiconductor chip 210.

The plurality of first through electrodes 212 connected to the first wiring structure and penetrate at least a portion of the first semiconductor chip 210. An uppermost first semiconductor chip 210T in a stack of first semiconductor chips 210T, which is arranged farthest from the interposer 100 and thus arranged uppermost in the semiconductor package 1 among the plurality of first semiconductor chips 210, may not include the plurality of first through electrodes 212. The first through electrodes 212 may include through silicon vias (TSV).

A vertical thickness of the uppermost first semiconductor chip 210T may be equal to or greater than a vertical thickness of each of the first semiconductor chips 210 that are not the uppermost first semiconductor chip 210T among a stack of the first semiconductor chips 210.

The first substrate 211 may be formed of and/or include, for example, a semiconductor material such as Si. The first semiconductor device may include various kinds of individual devices. The plurality of first semiconductor chips 210 may include memory chips which may each include memory cells, and the plurality of first semiconductor chips 210 may not include a buffer chip. The plurality of first semiconductor chips 210 may include high bandwidth memories (HBMs) that do not include a buffer chip. The first semiconductor chips 210 may include a dynamic random access memory (DRAM) die. For example, the first semiconductor chips 210 may communicate directly with the first embedded semiconductor chip 140 without a buffer chip, which traditionally may be used to temporarily store and arrange data sent between a logic chip and a memory chip, or other semiconductor chip providing a communication interface between the first semiconductor chips 210 and the embedded semiconductor chip 140.

The first bridge chip 220 may be provided on the interposer 100 between the first semiconductor chip stack CS1 and the second semiconductor chip stack CS2. The first bridge chip 220 may include the plurality of second chip pads 222 on a lower surface thereof, and may be electrically connected to the plurality of second upper connection pads 114B through the plurality of second chip connection terminals 115B. A first bridge wiring area 221A may be provided adjacent to a lower surface of the first bridge chip 220. The first bridge wiring area 221A may have a wiring structure for transmitting electrical signals of the first semiconductor chip stack CS1, the second semiconductor chip stack CS2, the first embedded semiconductor chip 140A, and the second embedded semiconductor chip 140B, which are connected to the first bridge wiring area 221A via the first wiring structure WL1. The first bridge chip 220 may be formed of and/or include a semiconductor substrate such as Si.

According an embodiment, the first bridge chip 220 of the semiconductor package 1 may be an active bridge chip. For example, the first bridge chip 220, which is not a passive bridge chip (e.g., a bridge chip not receiving power), may receive electrical power and transmit the electrical power. For example, the first bridge chip 220 may receive electrical power via at least some of the first conductive posts CP1 provided in the interposer 100. In this manner, the first bridge chip 220 may perform functions, such as signal amplification, regeneration, and switching together with the transfer of electrical signals to and/or from the first semiconductor chip stack CS1, the second semiconductor chip stack CS2, the first embedded semiconductor chip 140A, and the second embedded semiconductor chip 140B. However, in some embodiments, the first bridge chip 220 of the semiconductor package 1 may be a passive bridge chip that does receive electrical power separately.

The first heat dissipation block 310A may be provided on the first bridge chip 220, between the first semiconductor chip stack CS1 and the second semiconductor chip stack CS2. For example, a plan shape of the first heat dissipation block 310A may correspond to a plan shape of the first bridge chip 220. A first heat transfer layer 320A may be arranged between the first heat dissipation block 310A and the first bridge chip 220. A plan shape of the first heat transfer layer 320A may be the same or substantially the same as the plan shape of the first heat dissipation block 310A or the plan shape of the first bridge chip 220. However, the inventive concept is not limited to the plan shape of the first heat transfer layer 320A.

The second heat dissipation block 310B may be provided on the interposer 100, and along the outer edge of the interposer 100. Alternatively, the second heat dissipation block 310B may be provided between the outer edge of the interposer 100 and the first semiconductor chip stack CS1, and between the outer edge of the interposer 100 and the second semiconductor chip stack CS2. In addition, as illustrated in FIG. 2, the second heat dissipation block 310B may have a shape that protrudes and extends from the outer edge of the interposer 100 toward the first bridge chip 220 between the first semiconductor chip stack CS1 and the second semiconductor chip stack CS2. The second heat dissipation block 310B may be spaced apart from the first heat dissipation block 310A.

The first heat dissipation block 310A and/or the second heat dissipation block 310B may be provided in the semiconductor package 1 as needed, and this arrangement may also be applied to other embodiments. For example, according to embodiments of the inventive concept, neither the first heat dissipation block 310A nor the second heat dissipation block 310B may be provided in the semiconductor packages.

The plan shape of the second heat dissipation block 310B may be provided to surround at least portions of the side surfaces of the first semiconductor chip stack CS1 and the second semiconductor chip stack CS2. However, in some embodiments, at least a portion of the side surfaces of the first semiconductor chip stack CS1 and the second semiconductor chip stack CS2 may not be surrounded by the second heat dissipation block 310B.

Vertical heights of the first heat dissipation block 310A and the second heat dissipation block 310B from the upper surface of the interposer 100 may be substantially the same as vertical heights of the first semiconductor chip stack CS1 and the second semiconductor chip stack CS2.

The first heat dissipation block 310A and the second heat dissipation block 310B may be formed of and/or include Si, or may be formed of and/or include a metal including at least one of Al, Cu, Ti, Ni, iron (Fe), Co, palladium (Pd), platinum (Pt), gold (Au), lead (Pb), silver (Ag), carbon (C), Sn, W, and chromium (Cr), or an alloy thereof.

The first heat transfer layer 320A and a second heat transfer layer 320B may include a thermal interface material (TIM). The first heat transfer layer 320A and the second heat transfer layer 320B may have a higher heat transfer rate than a general adhesive material. The first heat transfer layer 320A and the second heat transfer layer 320B may attach the first heat dissipation block 310A and the second heat dissipation block 310B to the upper surface of the first bridge chip 220 and the upper surface of the interposer 100, and transfer heat generated inside the semiconductor package 1 to the first heat dissipation block 310A and the second heat dissipation block 310B, respectively. For example, the first heat transfer layer 320A and the second heat transfer layer 320B may transfer heat, generated by the first embedded semiconductor chip 140A, the second embedded semiconductor chip 140B, and the first bridge chip 220, to the first heat dissipation block 310A and the second heat dissipation block 310B, respectively.

The first heat transfer layer 320A and the second heat transfer layer 320B may have a structure in which a polymer material includes a filler such as metal particles dispersed in the polymer material. The heat dissipation interface material may include, for example, grease, or particle filled epoxy.

The second encapsulation member 330 may be provided on the interposer 100 to surround the first semiconductor chip stack CS1, the second semiconductor chip stack CS2, the first heat dissipation block 310A, the second heat dissipation block 310B, and the first bridge chip 220. The second encapsulating member 330 may be formed of and/or include an EMC, and may further include a filler. An upper surface of the second encapsulation member 330 may be coplanar with the upper surface of the first semiconductor chip stack CS1, the upper surface of the second semiconductor chip stack CS2, the upper surface of the first heat dissipation block 310A, and the upper surface of the second heat dissipation block 310B. As illustrated in FIG. 1, the second encapsulation member 330 may be arranged between each of the first semiconductor chips 210. Alternatively, in some embodiments, NCF or a non-conductive paste (NCP) may be arranged between each of the first semiconductor chips 210.

The configuration of the second encapsulation member 330 may be the same or substantially similar in other embodiments and a repeated description may be omitted hereafter.

In a plan view as illustrated in FIG. 2, a plan shape of the first embedded semiconductor chips 140A may have a greater area than the area of the plan shape of the first semiconductor chip stack CS1. Likewise, the area of a plan shape of the second embedded semiconductor chip 140B may be greater than the area of the plan shape of the second semiconductor chip stack CS2. For example, the first embedded semiconductor chip 140A may overlap the first semiconductor chip stack CS1 in the vertical direction, and the second embedded semiconductor chip 140B may overlap the second semiconductor chip stack CS2 in the vertical direction.

As illustrated in FIG. 2, in a plan view, a portion of the first bridge chip 220 and a portion of the first embedded semiconductor chip 140A may overlap in the vertical direction. In addition, in a plan view, another portion of the first bridge chip 220 and another portion of the second embedded semiconductor chip 140B may overlap in the vertical direction.

In the semiconductor package 1 according to the embodiment, the first semiconductor chip stack CS1 may be arranged adjacent to the first embedded semiconductor chip 140A, which may be a logic semiconductor chip, with the first wiring structure WL1 arranged therebetween. Accordingly, the efficiency of electrical signal transfer between the first semiconductor chip stack CS1 and the first embedded semiconductor chip 140A may be improved relative to if the first semiconductor chip stack CS1 and the first embedded semiconductor chip 140A were not adjacent. Similarly, efficiency of electrical signal transfer between the second semiconductor chip stack CS2 and the second embedded semiconductor chip 140B may be improved. The signal transfer characteristics of the semiconductor package 1 may be improved as a result.

The first embedded semiconductor chip 140A and the second embedded semiconductor chip 140B may exchange electrical signals through the first bridge chip 220. Because the first wiring structure WL1 is arranged between the first embedded semiconductor chip 140A, the second embedded semiconductor chip 140B, and the first bridge chip 220, the efficiency of electrical signal transfer between the first embedded semiconductor chip 140A, the second embedded semiconductor chip 140B, and the first bridge chip 220 may be improved. According to the structure of the semiconductor package 1 described above, the efficiency of signal transfer between a plurality of semiconductor chips included in the semiconductor package 1 may be improved, and thus the signal transfer characteristics of the semiconductor package 1 may be improved as well. The effect of an improvement of the signal transmission characteristics of the semiconductor package 1 described above may be achievable in all semiconductor packages of the inventive concept, and although not described separately below, those of skill in the art may understand that all of the semiconductor packages disclosed in the inventive concept have the same effect.

The second heat dissipation blocks 310B may be provided, with the first wiring structure WL1 arranged therebetween, above the first embedded semiconductor chip 140A and the second embedded semiconductor chip 140B, which are logic chips provided inside the interposer 100, and the first heat dissipation block 310A may be provided on the first bridge chip 220. Accordingly, heat dissipation of the first embedded semiconductor chip 140A, the second embedded semiconductor chip 140B, and the first bridge chip 220 may be effectively achieved. In addition, the second heat dissipation block 310B may be provided to surround the first semiconductor chip stack CS1 and the second semiconductor chip stack CS2 in an embracing manner. Thus, the second heat dissipation block 310B may easily transfer heat generated by the first semiconductor chip stack CS1 and the second semiconductor chip stack CS2, and effectively dissipate heat to the outside of the second heat dissipation block 310B. Therefore, heat dissipation characteristics of the semiconductor package 1 according to embodiments of the inventive concept may be improved. The effect of the improvement of the heat dissipation characteristics of the semiconductor package 1 described above may be achievable in all semiconductor packages of the inventive concept, and although not described separately below, those of skill in the art may understand that all of the semiconductor packages in the inventive concept have the same effect.

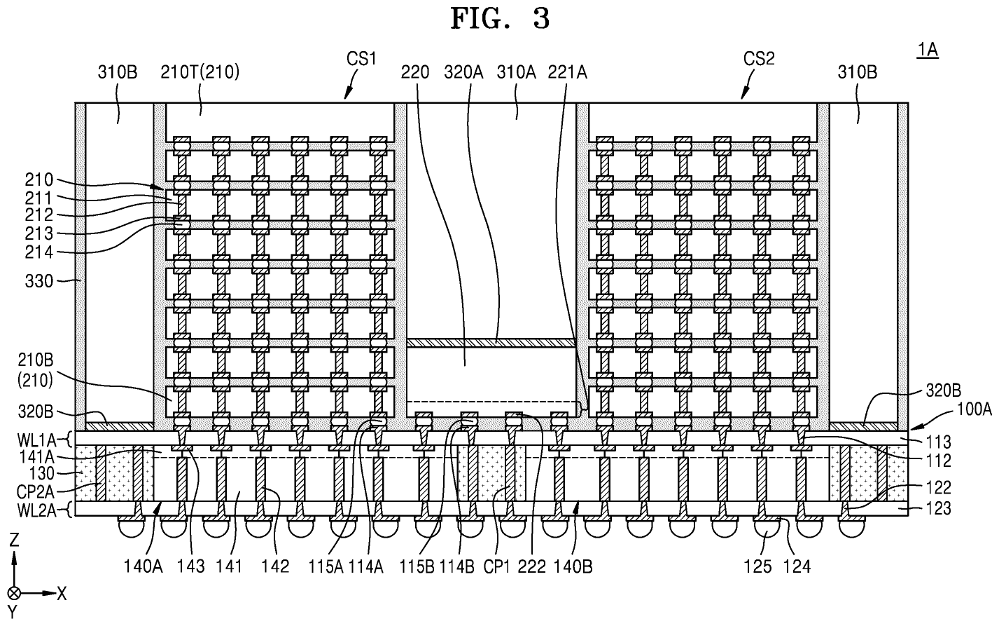

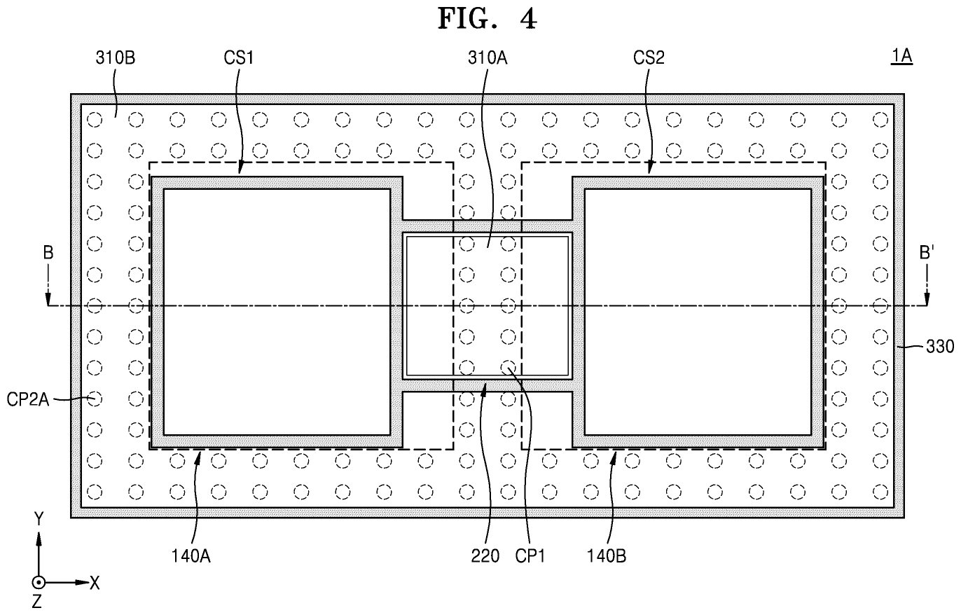

FIG. 3 is a cross-sectional view of a semiconductor package 1A according to an embodiment. FIG. 4 is a plan view of the semiconductor package 1A according to an embodiment. FIG. 3 is a cross-sectional view taken by cutting portion B-B′ in FIG. 4. Descriptions that would be the same or substantially the same as the descriptions given above may be omitted below with the understanding the preceding description is applicable.

Referring to FIGS. 3 and 4, the semiconductor package 1A may include an interposer 100A, the first semiconductor chip stack CS1 provided on the interposer 100A, the second semiconductor chip stack CS2 spaced apart from the first semiconductor chip stack CS1 in a lateral direction on the interposer 100A, the first bridge chip 220 provided between the first semiconductor chip stack CS1 and the second semiconductor chip stack CS2, the first heat dissipation block 310A provided on the first bridge chip 220 between the first semiconductor chip stack CS1 and the second semiconductor chip stack CS2, and the second heat dissipation block 310B provided to extend along an outer edge of the interposer 100A on the interposer 100A.

The interposer 100A may include a second wiring structure WL2A, the first embedded semiconductor chip 140A, the second embedded semiconductor chip 140B, the plurality of first conductive posts CP1, a plurality of second conductive posts CP2A, the first encapsulating member 130, and a first wiring structure WL1A. The first embedded semiconductor chip 140A may be provided on the second wiring structure WL2A. The second embedded semiconductor chip 140B may be spaced apart from the first embedded semiconductor chip 140A in a lateral direction on the second wiring structure WL2A. The plurality of first conductive posts CP1 may be provided between the first embedded semiconductor chip 140A and the second embedded semiconductor chip 140B. The plurality of second conductive posts CP2A may be provided on the second wiring structure WL2A between the outer edge of the second wiring structure WL2A and the first embedded semiconductor chip 140A and between the outer edge of the second wiring structure WL2A and the second embedded semiconductor chip 140B. The first encapsulating member 130 may surround the plurality of first conductive posts CP1, the plurality of second conductive posts CP2A, the first embedded semiconductor chip 140A, and the second embedded semiconductor chip 140B. The first wiring structure WL1A may be provided on the first embedded semiconductor chip 140A, the second embedded semiconductor chip 140B, and the first encapsulating member 130.

For example, the second wiring structure WL2A may include a single second insulating layer 123 and the plurality of second via patterns 122. Alternatively, as illustrated in the semiconductor package 1 of FIGS. 1 and 2, the second wiring structure may have a plurality of second insulating layers 123 and a plurality of second wiring patterns.

The first wiring structure WL1A may include a single first insulating layer 113 and the plurality of first via patterns 112. The first via patterns 112 may respectively correspond to the first upper connection pads 114A and the second upper connection pads 114B provided on the first wiring structure WL1A. In addition, the via patterns 112 may be respectively connected to the embedded chip pads 143, which are provided in the first embedded semiconductor chip 140A and the second embedded semiconductor chip 140B. Furthermore, the first via patterns 112 may be respectively connected to the first conductive posts CP1.

For example, the first via patterns 112 may respectively correspond to the first upper connection pads 114A and the second upper connection pads 114B on the upper surface of the first wiring structure WL1A and the first via patterns 112 may respectively correspond to and be connected to the embedded chip pads 143 of the first embedded semiconductor chip 140A, the embedded chip pads 143 provided on the second embedded semiconductor chip 140B, and the first conductive posts CP1 under the lower surface of the first wiring structure WL1A.

Unlike the first conductive posts CP1, the second conductive posts CP2A may not be electrically connected to the first via patterns 112. The second conductive posts CP2A may not be electrically connected to the first wiring structure WL1A. Accordingly, the second conductive posts CP2A may not be electrically connected to the semiconductor chips provided in the semiconductor package 1A.

The second conductive post CP2A may be provided on the second wiring structure WL2A along an outer edge of the second wiring structure WL2A or an outer edge of the interposer 100A. For example, the plurality of second conductive posts CP2 may be provided between the first embedded semiconductor chip 140A, the second embedded semiconductor chip 140B, and the outer edge of the second wiring structure WL2A.

The plurality of second conductive posts CP2A provided in the semiconductor package 1A according to the embodiment may be formed of and/or include a metal and the second conductive posts CP2A may be arranged adjacent to the first embedded semiconductor chip 140A and the second embedded semiconductor chip 140B in a lateral direction. Heat generated by the first embedded semiconductor chip 140A and the second embedded semiconductor chip 140B may be effectively discharged to the outside via the plurality of second conductive posts CP2A. The plurality of second conductive posts CP2A may quickly transfer heat to the second heat dissipation block 310B provided above the plurality of second conductive posts CP2A, and the heat dissipation of the first embedded semiconductor chip 140A and the second embedded semiconductor chip 140B may be effectively achieved.

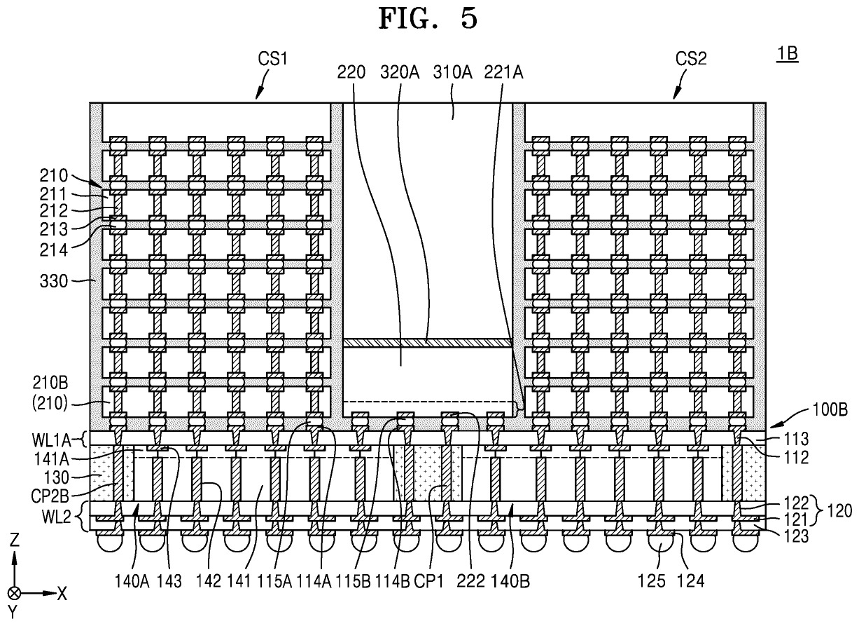

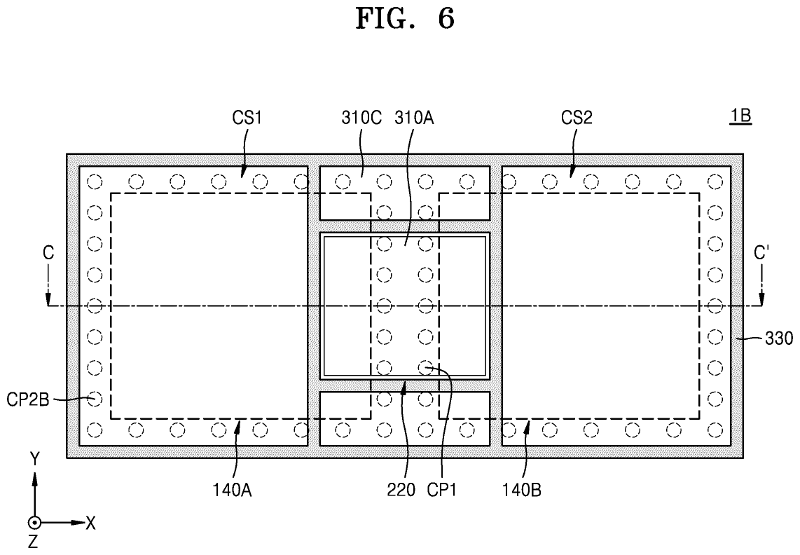

FIG. 5 is a cross-sectional view of a semiconductor package 1B according to an embodiment. FIG. 6 is a plan view of the semiconductor package 1B according to an embodiment. FIG. 5 is a cross-sectional view taken by cutting portion C-C′ in FIG. 6. Descriptions of elements not given in detail below may be the same or substantially the same as the descriptions given of the same or substantially similar elements above.

Referring to FIGS. 5 and 6, the semiconductor package 1A may include an interposer 100B, the first semiconductor chip stack CS1 provided on the interposer 100B, the second semiconductor chip stack CS2 spaced apart from the first semiconductor chip stack CS1 in a lateral direction on the interposer 100B, the first bridge chip 220 provided between the first semiconductor chip stack CS1 and the second semiconductor chip stack CS2, and the first heat dissipation block 310A provided on the first bridge chip 220 between the first semiconductor chip stack CS1 and the second semiconductor chip stack CS2. The semiconductor package 1A may further include a third heat dissipation block 310C provided between the first semiconductor chip stack CS1, the second semiconductor chip stack CS2, and the first bridge chip 220, on the interposer 110B.

The interposer 100B may include a second wiring structure WL2, a first embedded semiconductor chip 140A provided on the second wiring structure WL2, a second embedded semiconductor chip 140B spaced apart from the first embedded semiconductor chip 140A in a lateral direction on the second wiring structure WL2A, a plurality of first conductive posts CP1 provided between the first embedded semiconductor chip 140A and the second embedded semiconductor chip 140B, a plurality of second conductive posts CP2B provided, on the second wiring structure WL2A, between the outer edge of the second wiring structure WL2A and the first embedded semiconductor chip 140A, and between the outer edge of the second wiring structure WL2A and the second embedded semiconductor chip 140B, a first encapsulating member 130 surrounding the plurality of first conductive posts CP1, the plurality of second conductive posts CP2B, the first embedded semiconductor chip 140A, and the second embedded semiconductor chip 140B, and a first wiring structure WL1A provided on the first embedded semiconductor chip 140A, the second embedded semiconductor chip 140B, and the first encapsulating member 130.

The second wiring structure WL2 may include one or more second insulating layers 123 and the plurality of second wiring patterns 120. The second wiring pattern 120 may include the plurality of second line patterns 121 and the plurality of second via patterns 122.

The first wiring structure WL1A may include one first insulating layer 113 and the plurality of first via patterns 112. The first via patterns 112 may respectively correspond to the first upper connection pads 114A and the second upper connection pads 114B, provided on the first wiring structure WL1A.

The first via patterns 112 may be respectively connected to the embedded chip pads 143, which are provided in the first embedded semiconductor chip 140A and the second embedded semiconductor chip 140B. The first via patterns 112 may respectively correspond to and be connected to the first conductive posts CP1 and the second conductive posts CP2B.

For example, the first via patterns 112 may respectively correspond to the first upper connection pads 114A and the second upper connection pads 114B, on the upper surface of the first wiring structure WL1A, and the first via patterns 112 may respectively correspond to and be connected to the embedded chip pads 143 of the first embedded semiconductor chip 140A, the embedded chip pads 143 provided on the second embedded semiconductor chip 140B, the first conductive posts CP1, and the second conductive posts CP2B, under the lower surface of the first wiring structure WL1A.

At least some of the second conductive posts CP2B may supply power to the first semiconductor chip stack CS1 and the second semiconductor chip stack CS2. At least some of the second conductive posts CP2B may supply electrical signals to the first semiconductor chip stack CS1 and the second semiconductor chip stack CS2. At least some of the first conductive posts CP1 may supply power to the first semiconductor chip stack CS1 and the second semiconductor chip stack CS2, or at least some of the first conductive posts CP1 may transfer electrical signals to the first semiconductor chip stack CS1 and the second semiconductor chip stack CS2.

In a plan view as illustrated in FIG. 6, for example, a portion of the first embedded semiconductor chip 140A may overlap a portion of the first semiconductor chip stack CS1 in the vertical direction, and a portion of the second embedded semiconductor chip 140B may overlap a portion of the second semiconductor chip stack CS2 in the vertical direction.

As described above, the third heat dissipation block 310C may be provided between the first semiconductor chip stack CS1, the second semiconductor chip stack CS2, and the first bridge chip 220, on the interposer 110B. The third heat dissipation block 310C may receive heat generated by the first embedded semiconductor chip 140A and the second embedded semiconductor chip 140B, which are provided in the interposer 110B, and dissipate heat to the outside. In addition, the third heat dissipation block 310C may receive heat generated by the first semiconductor chip stack CS1, the second semiconductor chip stack CS2, and the first bridge chip 220, and dissipate heat to the outside.

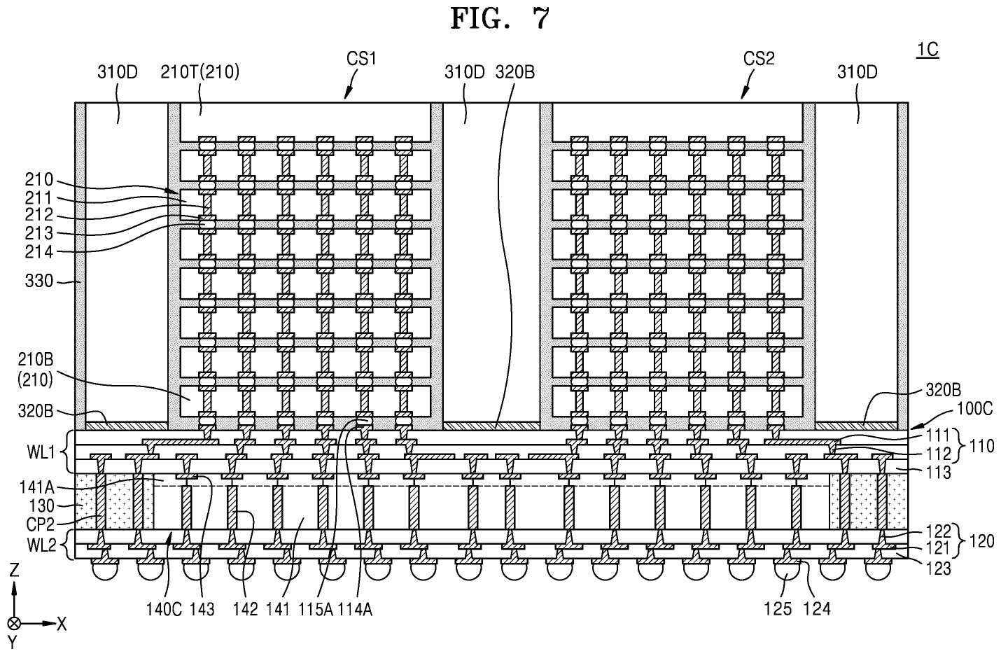

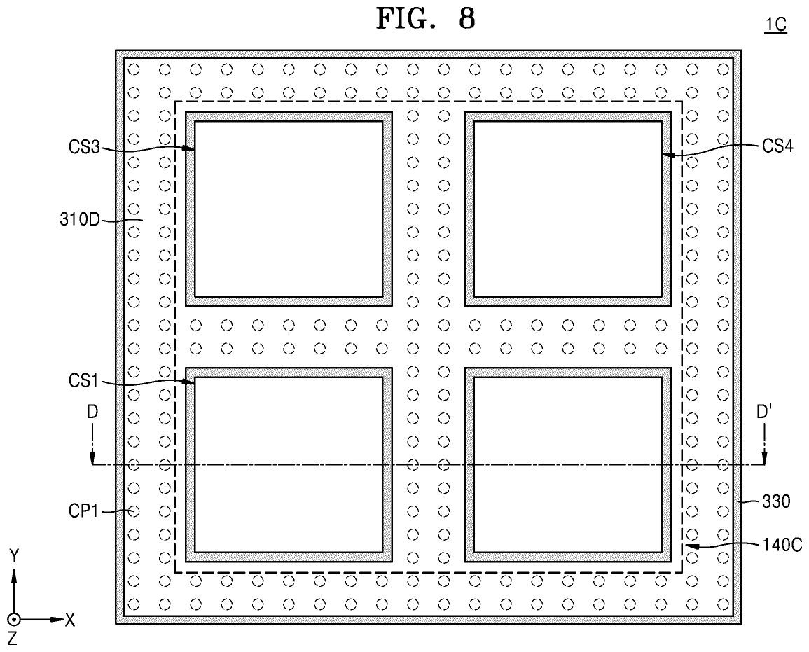

FIG. 7 is a cross-sectional view of a semiconductor package 1C according to an embodiment. FIG. 8 is a plan view of the semiconductor package 1C according to an embodiment. FIG. 7 is a cross-sectional view taken by cutting portion D-D′ in FIG. 8. Descriptions not given in detail below may be substantially the same as the descriptions given above.

Referring to FIGS. 7 and 8, the semiconductor package 1C may include an interposer 100C, the first semiconductor chip stack CS1, the second semiconductor chip stack CS2, a third semiconductor chip stack CS3, and a fourth semiconductor chip stack CS4, which are arranged on the 100C, and a fourth heat dissipation block 310D surrounding the first through fourth semiconductor chip stacks CS1 through CS4 and extending along the outer edges of the interposer 100C.

Because the third semiconductor chip stack CS3 and the fourth semiconductor chip stack CS4 are substantially the same as the first semiconductor chip stack CS1 and the second semiconductor chip stack CS2, except for the arrangement locations, detailed descriptions of the third semiconductor chip stack CS3 and the fourth semiconductor chip stack CS4 may be omitted.

The interposer 100C may include the second wiring structure WL2, a third embedded semiconductor chip 140C provided on the second wiring structure WL2, the plurality of second conductive posts CP2 provided between the outer edge of the second wiring structure WL2 and the third embedded semiconductor chip 140C, on the second wiring structure WL2, the first encapsulating member 130 surrounding the third embedded semiconductor chip 140C, and the first wiring structure WL1 provided on the first encapsulating member 130.

In a plan view as illustrated in FIG. 8, the areas of a plan shape of the third embedded semiconductor chip 140C may be greater than the area of a plan shape of each of the first through fourth semiconductor chip stacks CS1 through CS4. For example, the area of the plan shape of the third embedded semiconductor chip 140C may be more than twice the area of the plan shape of each of the first through fourth semiconductor chip stacks CS1 through CS4.

At least a portion of the plan shapes of the first through fourth semiconductor chip stacks CS1 through CS4 may overlap the plan shape of the third embedded semiconductor chip 140C in the vertical direction. For example, as illustrated in FIG. 8, all of the plan shapes of the first through fourth semiconductor chip stacks CS1 through CS4 may overlap the plan shape of the third embedded semiconductor chip 140C in the vertical direction.

The third embedded semiconductor chip 140C may include the first embedded substrate 141, the plurality of embedded through electrodes 142 vertically penetrating at least a portion of the first embedded substrate 141, the first active surface 141A provided adjacent to an upper surface of the first embedded substrate 141, and the plurality of embedded chip pads 143. The first embedded substrate 141 may include the first active surface 141A and an inactive surface opposite to the first active surface 141A. The first active surface 141A of the third embedded semiconductor chip 140C may be provided adjacent to an upper surface of the third embedded semiconductor chip 140C than a lower surface of the third embedded semiconductor chip 140C. For example, the third embedded semiconductor chip 140C may be arranged such that the first active surface 141A of the third embedded semiconductor chip 140C is closer to the first wiring structure WL1 than the second wiring structure WL2.

The third embedded semiconductor chip 140C may include a logic semiconductor chip. The logic semiconductor chip may include, for example, a CPU, a GPU, an FPGA, an AP, a digital signal processor, an encryption processor, a controller, or an ASIC.

In the semiconductor package 1C according to the embodiment, the first through fourth semiconductor chip stacks CS1 through CS4 may be arranged adjacent to the third embedded semiconductor chip 140C, which is a logic semiconductor chip, with the first wiring structure WL1 arranged therebetween. Accordingly, the efficiency of electrical signal transfer between the first through fourth semiconductor chip stacks CS1 through CS4 and the third embedded semiconductor chip 140C may be improved. For example, signal transfer characteristics of the semiconductor package 1C may be improved.

In addition, the semiconductor package 1C according to the embodiment may include a fourth heat dissipation block 310D adjacent to the third embedded semiconductor chip 140C, which is a logic semiconductor chip. The fourth heat dissipation block 310D may receive heat generated by the third embedded semiconductor chip 140C, and may effectively dissipate heat to the outside. Therefore, heat dissipation characteristics of the semiconductor package 1C according to embodiments of the inventive concept may be improved.

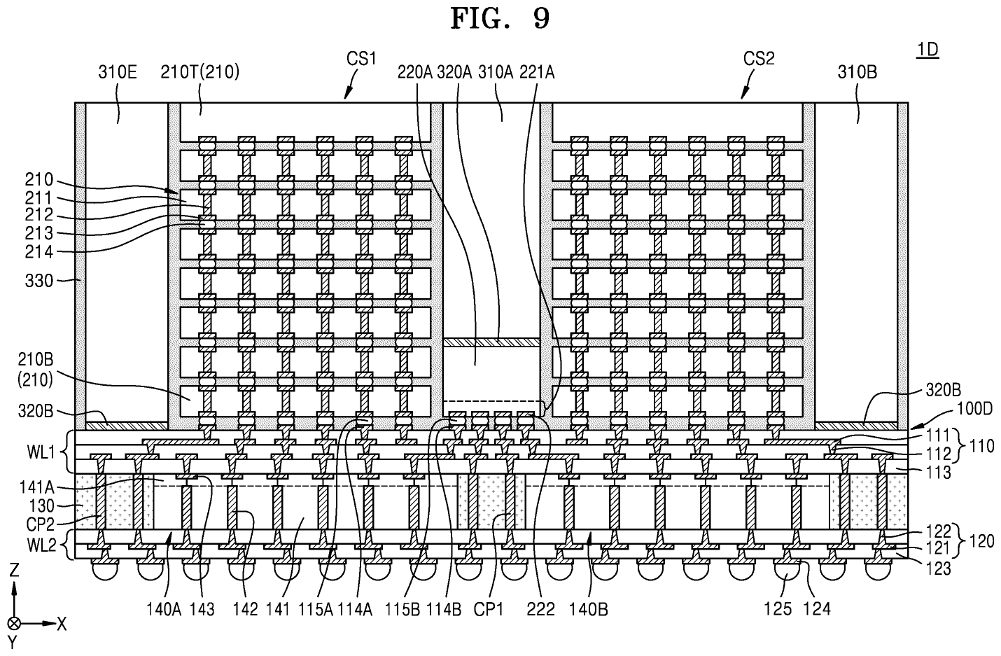

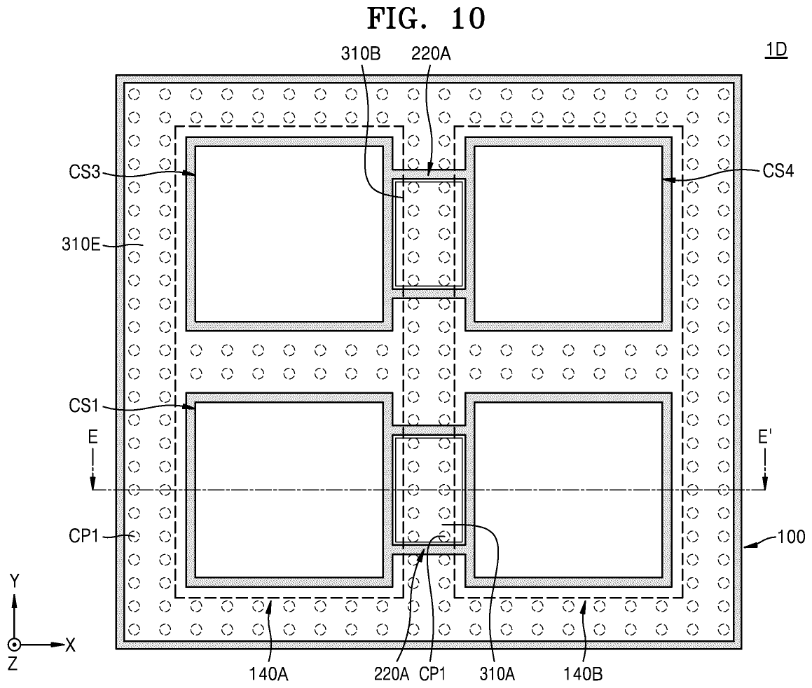

FIG. 9 is a cross-sectional view of a semiconductor package 1D according to an embodiment. FIG. 10 is a plan view of the semiconductor package 1D according to an embodiment. FIG. 9 is a cross-sectional view taken by cutting portion E-E′ in FIG. 10. Descriptions not given in detail below may be substantially the same as the descriptions given above.

Referring to FIGS. 9 and 10, the semiconductor package 1D may include an interposer 100D, the first through fourth semiconductor chip stacks CS1 through CS4 provided on the interposer 100D, a first bridge chip 220A provided between the first semiconductor chip stack CS1 and the second semiconductor chip stack CS2, a second bridge chip 220B provided between the third semiconductor chip stack CS3 and the fourth semiconductor chip stack CS4, the first heat dissipation block 310A provided on each of the first bridge chip 220A and the second bridge chip 220B, and a second heat dissipation block 310E extending between the outer edge of the interposer 100D and each of the first through fourth semiconductor chip stacks CS1 through CS4 and between each of the first through fourth semiconductor chip stacks CS1 through CS4.

The interposer 100D may include the second wiring structure WL2, the first embedded semiconductor chip 140A provided on the second wiring structure WL2, the second embedded semiconductor chip 140B spaced apart from the first embedded semiconductor chip 140A in a lateral direction on the second wiring structure WL2, the plurality of first conductive posts CP1 provided between the first embedded semiconductor chip 140A and the second embedded semiconductor chip 140B, the plurality of second conductive posts CP2 provided, on the second wiring structure WL2, on the outer edge of the first embedded semiconductor chip 140A, and the outer edge of the second embedded semiconductor chip 140B, the first encapsulating member 130 surrounding the plurality of first conductive posts CP1, the plurality of second conductive posts CP2, the first embedded semiconductor chip 140A, and the second embedded semiconductor chip 140B, and the first wiring structure WL1 provided on the first embedded semiconductor chip 140A, the second embedded semiconductor chip 140B, and the first encapsulating member 130.

In a plan view as illustrated in FIG. 10, the area of a plan shape of the first embedded semiconductor chip 140A may be greater than the area of plan shapes of the first semiconductor chip stack CS1 and the third semiconductor chip stack CS3. The area of plan shape of the second embedded semiconductor chip 140B may be greater than the area of the plan shapes of the second semiconductor chip stack CS2 and the fourth semiconductor chip stack CS4. The plan shape of the first embedded semiconductor chip 140A may respectively overlap at least a portion of the plan shape of the first semiconductor chip stack CS1 and at least a portion of the plan shape of the third semiconductor chip stack CS3 in the vertical direction. The plan shape of the second embedded semiconductor chip 140B may respectively overlap at least a portion of the plan shape of the second semiconductor chip stack CS2 and at least a portion of the plan shape of the fourth semiconductor chip stack CS4 in the vertical direction.

As illustrated in FIG. 10, a portion of the first bridge chip 220A may overlap a portion of the first embedded semiconductor chip 140A in the vertical direction, and the remaining portion of the first bridge chip 220A may overlap a portion of the second embedded semiconductor chip 140B in the vertical direction. Similarly, a portion of the second bridge chip 220B may overlap a portion of the first embedded semiconductor chip 140A in the vertical direction, and the remaining portion of the second bridge chip 220B may overlap a portion of the second embedded semiconductor chip 140B in the vertical direction.

In other embodiments, only a single bridge chip, rather than a plurality of bridge chips, such as the first bridge chip 220A and the second bridge chip 220B, may be provided on the interposer 110D. For example, one or more bridge chips may be provided between the first embedded semiconductor chip 140A and the second embedded semiconductor chip 140B in a plan view, rather than a single bridge chip provided between each semiconductor chip stack of a plurality of semiconductor chip stacks. For example, a bridge chip may be provided at a center portion adjacent to and between first through fourth semiconductor chip stacks CS1 through CS4 on the upper surface of the interposer 100D.

The second heat dissipation block 310E may extend between the first through fourth semiconductor chip stacks CS1 through CS4 and the outer edge of the interposer 100D, and between each of the first through fourth semiconductor chip stacks CS1 through CS4, and may be provided on the interposer 100D. Accordingly, the second heat dissipation block 310E may extend between each of the first through fourth semiconductor chip stacks CS1 through CS4, which do not include the first bridge chip 220A and the second bridge chip 220B.

In FIG. 10, a portion of the second heat dissipation block 310E provided between the first through fourth semiconductor chip stacks CS1 through CS4 and the outer edge of the interposer 100D, and a portion of the second heat dissipation block 310E extending between each of the first through fourth semiconductor chip stacks CS1 through CS4 are illustrated as one integral body. However, in some embodiments, a portion of the second heat dissipation block 310E provided between the first through fourth semiconductor chip stacks CS1 through CS4 and the outer edge of the interposer 100D, and a portion of the second heat dissipation block 310E extending between each of the first through fourth semiconductor chip stacks CS1 through CS4 may be divided and mounted on the interposer 100D. For example, the second heat dissipation block 310E may be mounted on the interposer 100D after being manufactured as a plurality of separate parts.

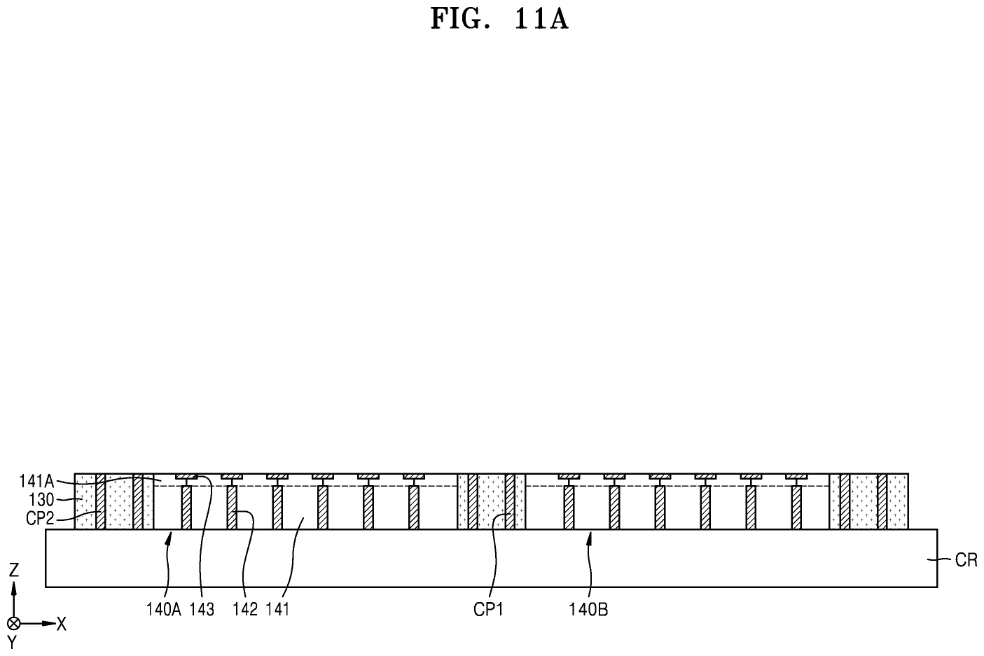

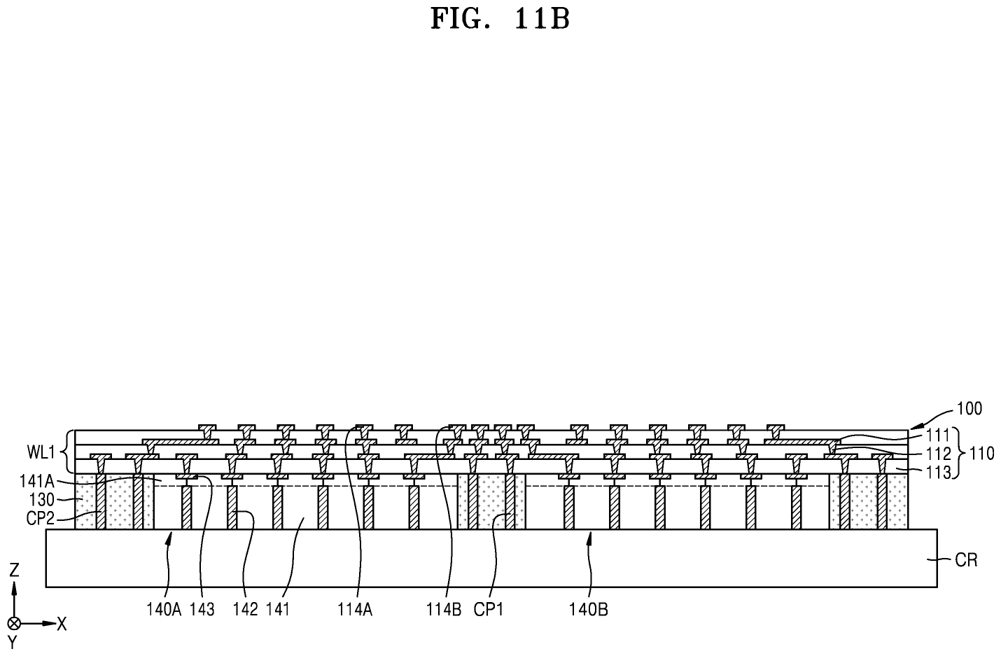

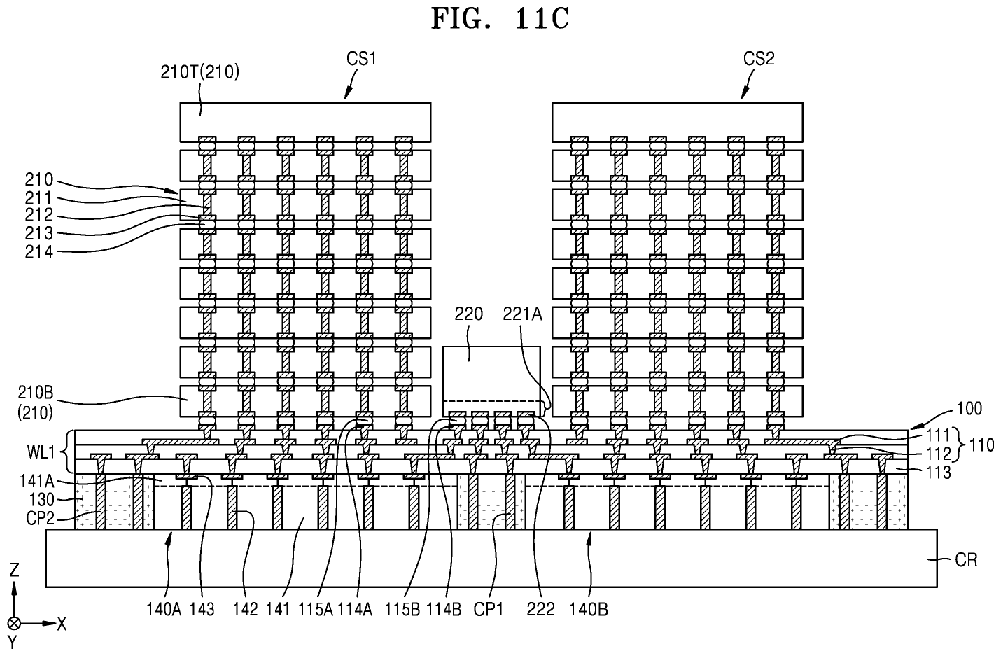

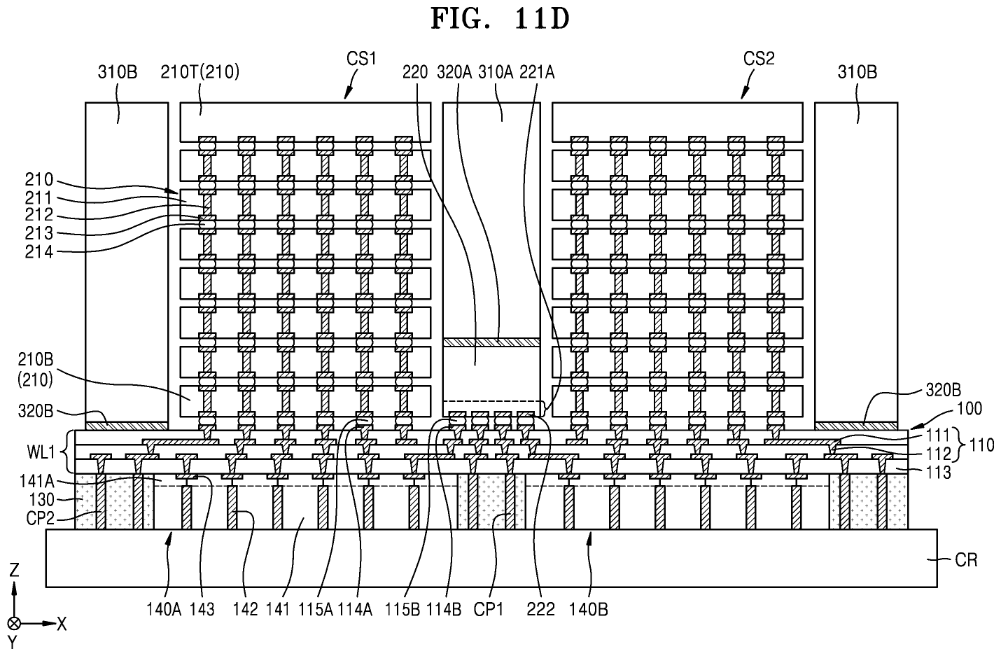

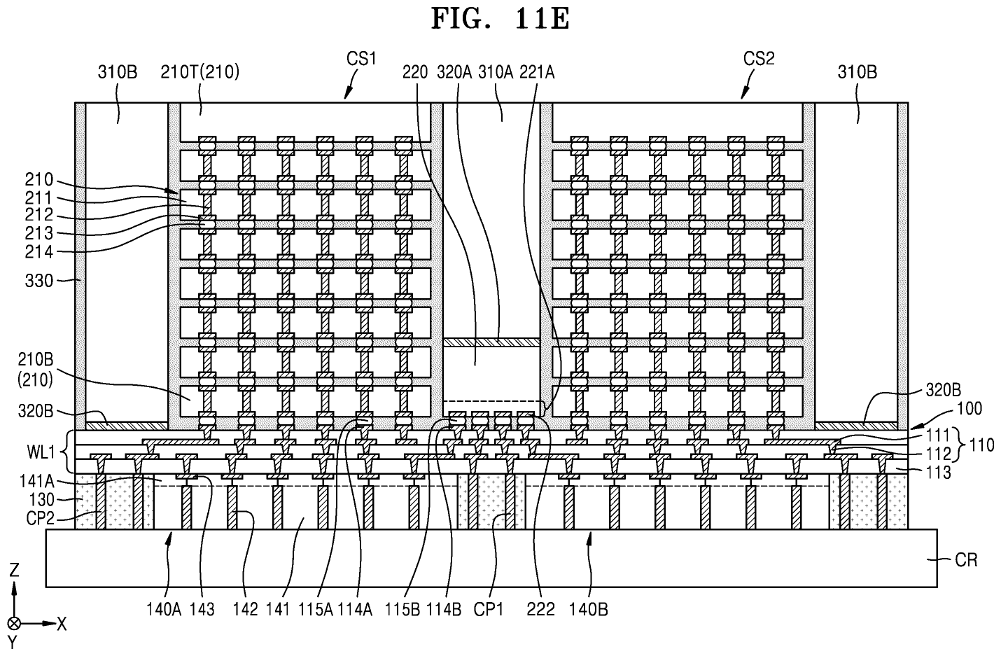

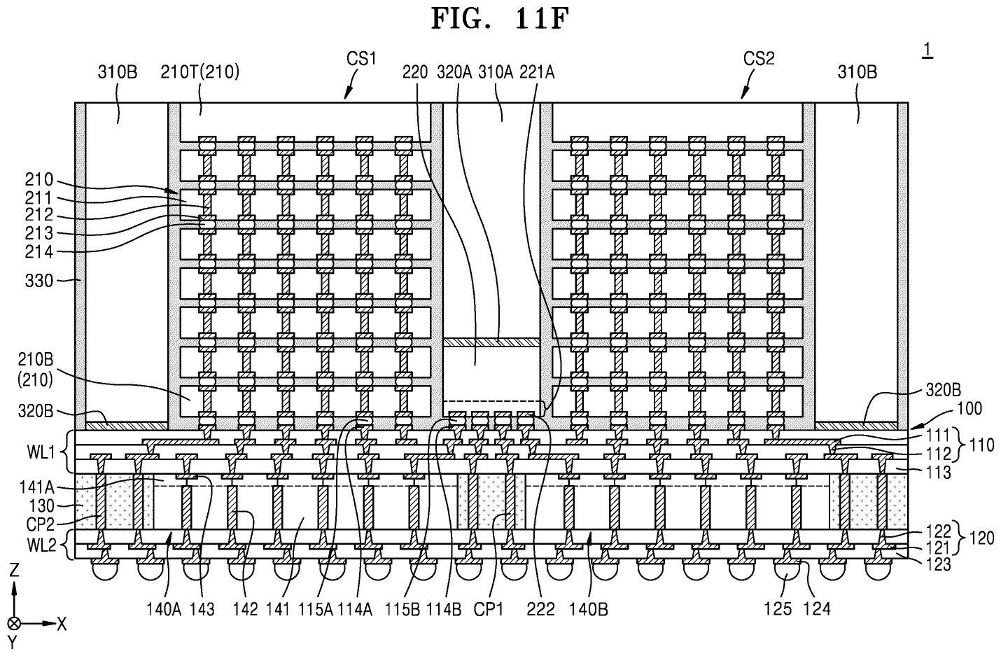

FIGS. 11A through 11F are cross-sectional views sequentially illustrating a manufacturing method of the semiconductor package 1 according to embodiments. Descriptions not given below may be substantially the same as the descriptions given above.

Referring to FIG. 11A, the first embedded semiconductor chip 140A, the second embedded semiconductor chip 140B, the plurality of first conductive posts CP1, and the plurality of second conductive posts CP2 may be arranged on a carrier CR, and the first encapsulating member 130 may be formed. Although not illustrated in detail, the process result of FIG. 11A may be formed in an inverted state with respect to FIG. 11A, and then may be arranged on the carrier CR.

After the plurality of embedded chip pads 143 provided in the first embedded semiconductor chip 140A and the second embedded semiconductor chip 140B are arranged on the carrier CR to face downward, the plurality of first conductive posts CP1 may be formed between the first embedded semiconductor chip 140A and the second embedded semiconductor chip 140B, and the second conductive post CP2 may be formed on the outer edges of the first embedded semiconductor chip 140A and the second embedded semiconductor chip 140B. Next, the first encapsulating member 130 may be formed to surround the plurality of first conductive posts CP1, the second conductive post CP2, the first embedded semiconductor chip 140A, and the second embedded semiconductor chip 140B. The first encapsulating member 130, the plurality of first conductive posts CP1, the second conductive post CP2, the first embedded semiconductor chip 140A, and the second embedded semiconductor chip 140B may be planarized by using a chemical mechanical polishing (CMP) process, and then the process result of FIG. 11A may be formed.

By using the CMP process, upper surfaces of each of the first encapsulating member 130, the plurality of first conductive posts CP1, the second conductive post CP2, the first embedded semiconductor chip 140A, and the second embedded semiconductor chip 140B may be coplanar, and lower surfaces of each of the first encapsulating member 130, the plurality of first conductive posts CP1, the second conductive post CP2, the first embedded semiconductor chip 140A, and the second embedded semiconductor chip 140B may be coplanar.

Referring to FIG. 11B, the first wiring structure WL1 may be formed on the process result of FIG. 11A. The first wiring structure WL1 may include the plurality of first insulating layers 113. The first wiring structure WL1 may be formed by using a rewiring process. The first wiring structure WL1 may include the plurality of first insulating layers 113 and the plurality of first wiring patterns 110. The first wiring pattern 110 may include a plurality of first line patterns 111 and a plurality of first via patterns 112. The rewiring process may mean a series of processes in which the first insulating layer 113 is formed, the first wiring pattern 110 is formed on the formed first insulating layer 113, and then the first insulating layer 113 is formed thereon again.

Referring to FIG. 11C, the first semiconductor chip stack CS1, the second semiconductor chip stack CS2, and the first bridge chip 220 may be mounted on the first wiring structure WL1 of the process result of FIG. 11B. As illustrated in the drawing in the inventive concept, the first semiconductor chip stack CS1 may include a stack of the plurality of first semiconductor chips 210, which are stacked by being connected to each other by using the plurality of first chip pads 213 and the first chip connection terminal 214. For example, the first semiconductor chip stack CS1 may be formed by a using a thermo-compression bonding process.

In some embodiments, two adjacent first semiconductor chips 210 among the plurality of first semiconductor chips 210 may be directly bonded to each other. The direct bonding of any two chips may include the direct bonding of conductive components at positions facing each other of the two chips, and the direct bonding of insulating components at positions facing each other of the two chips. The direct bonding of the insulating components may include forming a chemical bond between the insulating components. The direct bonding of any two chips may include hybrid bonding.

For example, a lower pad arranged on the lower surface of the first semiconductor chip 210 may be directly bonded to an upper pad arranged on the upper surface of another adjacent first semiconductor chip 210. During the direct bonding process, metal atoms in the lower pad and the metal atoms in the upper pad may diffuse to each other. Accordingly, the interfaces of the upper pad and the lower pad may be bonded so that the interfaces may not be distinguished from each other. The lower pad and the upper pad, which are integrated by using a direct bonding process in this manner, may be collectively referred to as a bonding pad. For example, the bonding pad may be formed of and/or include a material such as Cu.

Referring to FIG. 11D, the first heat dissipation block 310A may be arranged on the first bridge chip 220 of the process result of FIG. 11C, and the second heat dissipation block 310B may be arranged on the first wiring structure WL1 of the process result of FIG. 11C. The first heat transfer layer 320A and the second heat transfer layer 320B may be arranged on a lower surface of the first heat dissipation block 310A and a lower surface of the second heat dissipation block 310B, respectively.

Referring to FIGS. 11E and 11F, the second encapsulation member 330 may be arranged on the first wiring structure WL1 of the process result of FIG. 11D. Thereafter, the carrier CR may be removed, a rewiring process may be performed, and the second wiring structure WL2 may be formed.

While the inventive concept has been particularly shown and described with reference to embodiments thereof, it will be understood that various change in form and details may be made therein without departing from the spirit and scope of the following claims.

What is claimed is:

1. A semiconductor package comprising:
an interposer;
a first semiconductor chip stack arranged on the interposer and including a plurality of first semiconductor chips;
a second semiconductor chip stack arranged on the interposer and including a plurality of second semiconductor chips, the second semiconductor chip stack spaced apart from the first semiconductor chip stack in a lateral direction; and
a first bridge chip arranged on the interposer between the first semiconductor chip stack and the second semiconductor chip stack,
wherein the interposer comprises a second wiring structure, a first wiring structure spaced apart from the second wiring structure in a vertical direction, a first embedded semiconductor chip arranged between the first wiring structure and the second wiring structure, a second embedded semiconductor chip arranged between the first wiring structure and the second wiring structure and spaced apart from the first embedded semiconductor chip in a lateral direction, and a plurality of first conductive posts arranged between the first embedded semiconductor chip and the second embedded semiconductor chip.

2. The semiconductor package of claim 1, further comprising a first heat dissipation block on the first bridge chip and arranged between the first semiconductor chip stack and the second semiconductor chip stack.

3. The semiconductor package of claim 1,
further comprising a second heat dissipation block on the interposer, the second heat dissipation block arranged along an outer edge of the interposer spaced apart from the first semiconductor chip stack and the second semiconductor chip stack, and the second heat dissipation block arranged on outer sides of the first semiconductor chip stack and outer sides of the second semiconductor chip stack.

4. The semiconductor package of claim 3,
wherein each of the first embedded semiconductor chip and the second embedded semiconductor chip comprises a logic chip, and
wherein each of a first active surface of the first embedded semiconductor chip and a second active surface of the second embedded semiconductor chip is arranged closer to the first wiring structure than to the second wiring structure.

5. The semiconductor package of claim 1,
wherein the first wiring structure is in contact with a first surface of the first embedded semiconductor chip and a second surface of the second embedded semiconductor chip, and the second wiring structure is in contact with a third surface of the first embedded semiconductor chip opposite the first surface and a fourth surface of the second embedded semiconductor chip opposite the second surface.

6. The semiconductor package of claim 1,
wherein the first wiring structure comprises a plurality of first insulating layers and a plurality of first wiring patterns, and the plurality of first wiring patterns respectively comprise a plurality of first line patterns and a plurality of first via patterns.

7. The semiconductor package of claim 1,
wherein the first wiring structure comprises a single first insulating layer and a plurality of first via patterns,
wherein the first embedded semiconductor chip comprises first embedded chip pads arranged on an upper surface of the first embedded semiconductor chip and the second embedded semiconductor chip comprises second embedded chip pads arranged on an upper surface of the second embedded semiconductor chip, and
wherein a first group of first via patterns of the plurality of first via patterns respectively correspond to the first embedded chip pads, a second group of first via patterns of the plurality of first via patterns respectively correspond to second embedded chip pads, and a third group of first via patterns of the plurality of first via patterns respectively correspond to the plurality of first conductive posts.

8. The semiconductor package of claim 1,
wherein the interposer comprises a plurality of second conductive posts,
wherein the plurality of second conductive posts are arranged between the first wiring structure and the second wiring structure, and
wherein a first group of second conductive posts of the plurality of second conductive posts are arranged between an outer edge of the interposer and the first embedded semiconductor chip, and a second group of second conductive posts of the plurality of second conductive posts are arranged between an outer edge of the interposer and the second embedded semiconductor chip.

9. The semiconductor package of claim 8,
wherein the plurality of second conductive posts are not electrically connected to the first wiring structure and the plurality of first conductive posts are electrically connected to the first wiring structure.

10. The semiconductor package of claim 8, wherein the first bridge chip receives power from a first conductive post of the plurality of first conductive posts and a second conductive post of the plurality of second conductive posts.

11. The semiconductor package of claim 1,
wherein a first portion of the first bridge chip overlaps a portion of the first embedded semiconductor chip in a vertical direction, and a second portion of the first bridge chip overlaps a portion of the second embedded semiconductor chip in the vertical direction.

12. The semiconductor package of claim 1,
wherein the interposer comprises a plurality of second conductive posts,
wherein the first wiring structure comprises a single first insulating layer and a plurality of first via patterns,
wherein the plurality of second conductive posts are arranged between the first wiring structure and the second wiring structure, and a first group of second conductive posts of the plurality of second conductive posts are arranged between an outer edge of the interposer and the first embedded semiconductor chip, and a second group of second conductive posts of the plurality of second conductive posts are arranged between the outer edge of the interposer and the second embedded semiconductor chip,
wherein the first embedded semiconductor chip comprises first embedded chip pads arranged on an upper surface of the first embedded semiconductor chip and the second embedded semiconductor chip comprises second embedded chip pads arranged on an upper surface of the second embedded semiconductor chip, and
wherein a first group of first via patterns of the plurality of first via patterns respectively correspond to the first embedded chip pads, a second group of first via patterns of the plurality of first via patterns respectively correspond to the second embedded chip pads, and a third group of first via patterns of the plurality of first via patterns respectively correspond to the plurality of first conductive posts, and a fourth group of first via patterns of the plurality of first via patterns respectively correspond to the plurality of second conductive posts.

13. The semiconductor package of claim 12,
wherein first chip pads arranged on a lowermost first semiconductor chip in the first semiconductor chip stack, second chip pads arranged on a lowermost second semiconductor chip in the second semiconductor chip stack, and a third chip pad of the first bridge chip respectively correspond to via patterns of the plurality of first via patterns.

14. The semiconductor package of claim 12,
wherein uppermost surfaces of the plurality of first conductive posts, the plurality of second conductive posts, the first embedded semiconductor chip, and the second embedded semiconductor chip form a coplanar surface.

15. The semiconductor package of claim 12, further comprising:
a first heat dissipation block arranged on the first bridge chip between the first semiconductor chip stack and the second semiconductor chip stack; and
a second heat dissipation block provided on the interposer between the first semiconductor chip stack and the second semiconductor chip stack, and between the outer edge of the interposer and the first bridge chip.

16. The semiconductor package of claim 1,
wherein the interposer comprises a plurality of second conductive posts,
wherein the plurality of second conductive posts are arranged between the first wiring structure and the second wiring structure, and a first group of second conductive posts of the plurality of second conductive posts are arranged between an outer edge of the interposer and the first embedded semiconductor chip, and a second group of second conductive posts of the plurality of second conductive posts are arranged between the outer edge of the interposer and the second embedded semiconductor chip, and
wherein a first conductive post of the plurality of first conductive posts supplies power to the first bridge chip, and a second conductive post of the plurality of second conductive posts supplies power to the first semiconductor chip stack.

17. A semiconductor package comprising:
an interposer;
a plurality of semiconductor chip stacks arranged on the interposer and each respectively including a plurality of semiconductor chips; and
a bridge chip arranged on the interposer,
wherein the interposer comprises a second wiring structure, a first wiring structure spaced apart from the second wiring structure in a vertical direction, a first embedded semiconductor chip arranged between the first wiring structure and the second wiring structure, a second embedded semiconductor chip arranged between the first wiring structure and the second wiring structure, the second embedded semiconductor chip spaced apart from the first embedded semiconductor chip in a lateral direction, and a plurality of first conductive posts arranged between the first embedded semiconductor chip and the second embedded semiconductor chip,
wherein the first embedded semiconductor chip overlaps a first group of semiconductor chips of the plurality of semiconductor chips in the vertical direction, and the second embedded semiconductor chip overlaps a second group of semiconductor chips of the plurality of semiconductor chips in the vertical direction, and
wherein a first portion of the bridge chip overlaps the first embedded semiconductor chip in the vertical direction, and a second portion of the bridge chip overlaps the second embedded semiconductor chip in the vertical direction.

18. The semiconductor package of claim 17, further comprising:
a first heat dissipation block arranged on the bridge chip between neighboring semiconductor chip stacks of the plurality of semiconductor chip stacks; and
a second heat dissipation block on the interposer, configured to extend along an outer edge of the interposer and between neighboring semiconductor chip stacks of the plurality of semiconductor chip stacks, and arranged spaced apart from the first heat dissipation block.

19. The semiconductor package of claim 17,
wherein the interposer comprises a plurality of second conductive posts,
wherein the plurality of second conductive posts are arranged between the first wiring structure and the second wiring structure,
wherein a first group of second conductive posts of the plurality of second conductive posts are arranged between an outer edge of the interposer and the first embedded semiconductor chip, and a second group of second conductive posts of the plurality of second conductive posts are arranged between an outer edge of the interposer and the second embedded semiconductor chip,
wherein the first wiring structure comprises a plurality of first insulating layers and a plurality of first wiring patterns, and the plurality of first wiring patterns respectively comprise a plurality of first line patterns and a plurality of first via patterns, and
wherein a first conductive post of the plurality of first conductive posts supplies power to the bridge chip, and a second conductive post of the plurality of second conductive posts supplies power to at least one semiconductor stack of the plurality of semiconductor chip stacks.

20. A semiconductor package comprising:
an interposer;
a first semiconductor chip stack arranged on the interposer and including a plurality of first semiconductor chips;
a second semiconductor chip stack arranged on the interposer and including a plurality of second semiconductor chips, the second semiconductor chip stack spaced apart from the first semiconductor chip stack in a lateral direction;
a bridge chip arranged on the interposer between the first semiconductor chip stack and the second semiconductor chip stack;
a first heat dissipation block arranged on the bridge chip between the first semiconductor chip stack and the second semiconductor chip stack; and
a second heat dissipation block on the interposer and configured to extend along an outer edge of the interposer and to extend between the first semiconductor chip stack and the second semiconductor chip stack, and spaced apart from the first heat dissipation block,
wherein the interposer comprises a second wiring structure, a first wiring structure spaced apart from the second wiring structure in a vertical direction, a first embedded semiconductor chip arranged between the first wiring structure and the second wiring structure, a second embedded semiconductor chip arranged between the first wiring structure and the second wiring structure, the second embedded semiconductor chip apart from the first embedded semiconductor chip in a lateral direction, and a plurality of first conductive posts arranged between the first embedded semiconductor chip and the second embedded semiconductor chip, and a plurality of second conductive posts,
wherein the plurality of second conductive posts are arranged between the first wiring structure and the second wiring structure, a first group of second conductive posts of the plurality of second conductive posts are arranged between an outer edge of the interposer and the first embedded semiconductor chip, and a second group of second conductive posts of the plurality of second conductive posts are arranged between the outer edge of the interposer and the second embedded semiconductor chip,
wherein the first wiring structure comprises a first insulating layer and a plurality of first via patterns,
wherein the first embedded semiconductor chip comprises a plurality of first electrodes extending in a vertical direction inside the first embedded semiconductor chip, and the second embedded semiconductor chip comprises a plurality of second electrodes configured to extend in a vertical direction inside the second embedded semiconductor chip,
wherein the first wiring structure is in contact with a first surface of the first embedded semiconductor chip and a second surface of the second embedded semiconductor chip, and the second wiring structure is in contact with a third surface of the first embedded semiconductor chip opposite the first surface and a fourth surface of the second embedded semiconductor chip opposite the second surface,
wherein a first conductive post of the plurality of first conductive posts supplies power to the bridge chip, and a second conductive post of the plurality of second conductive posts supplies power to the first semiconductor chip stack, and
wherein each of a first active surface of the first embedded semiconductor chip and a second active surface of the second embedded semiconductor chip is arranged closer to the first wiring structure than to the second wiring structure.
